(19) United States
(12) Patent Application Publication
(10) Pub. No.: US 2018/0284169 A1
(43) Pub. Date: Oct. 4, 2018

(54) APPARATUS, SYSTEM AND METHOD FOR ENERGY MANAGEMENT

(71) Applicant: TEMASEK POLYTECHNIC, Singapore (SG)

(72) Inventors: Kian Hoong KWAN, Singapore (SG); Gucheng WANG, Singapore (SG); Wenwen WANG, Singapore (SG); Chaw Poh CHIA, Singapore (SG); Woie Seng HOW, Singapore (SG); Kai Thong Mariner KWOK, Singapore (SG); Supun Tharindu ARIYASINGHE OWALAKANKANAMALAGE, Singapore (SG)

(21) Appl. No.: 15/764,321

(22) PCT Filed: Sep. 27, 2016
(86) PCT No.: PCT/SG2016/050477

§ 371 Date: Mar. 28, 2018

(30) Foreign Application Priority Data
Sep. 28, 2015 (SG) 10201508067W

(51) Int. Cl. G01R 21/133; H02J 3/14; H02J 13/00; H02B 1/48; H02B 1/20; H02B 1/04

(52) U.S. Cl. CPC G01R 21/133; H02J 3/14; H02B 1/04; H02B 1/48; H02B 1/20; H02J 13/0017

(57) ABSTRACT

An apparatus for installation with an electrical distribution box comprising a bus bar and a plurality of circuit breakers, the apparatus comprises a sensor circuit comprising at least one sensor arranged in series connection with the bus bar and one of the plurality of circuit breakers, wherein one end of the at least one sensor is connected to the bus bar and another end of the at least one sensor is connected to one of the plurality of circuit breakers; and a processor to obtain a corresponding voltage signal and a corresponding current signal flowing through the at least one sensor.

### FIELD OF THE INVENTION

The present invention relates to an apparatus, system and method for monitoring and managing electrical energy usage.

### BACKGROUND ART

The following discussion of the background to the invention is intended to facilitate an understanding of the present invention only. It should be appreciated that the discussion is not an acknowledgement or admission that any of the material referred to was published, known or part of the common general knowledge of the person skilled in the art in any jurisdiction as at the priority date of the invention.

With the advent of technology such as Big Data analytics and Internet of things (IOT), electrical consumption of a premise can be obtained as data by ‘smart’ devices for analysis. Such analysis may be useful for extraction of useful information for monitoring and energy management.

One type of ‘smart’ device is a smart plug which is typically installed at an electrical socket to obtain electricity consumption data of the device plugged to the electrical socket. However, for a number of electrical sockets the same corresponding number of smart plugs have to be installed. This results in increased costs.

Another type of smart device is a smart meter installed along the electricity distribution line before an electrical distribution board. The smart meter obtains data relating to the overall electrical consumption of a premise (e.g. a residential household) in a centralized manner but is unable to provide an indication of individual electrical consumption associated with each appliance.

Another type of smart device is a smart distribution panel which is typically deployed at switch room of large premises such as commercial buildings, shopping malls, hotels, etc. Although such smart distribution panel may possibly obtain an indication of the electrical consumption associated with a group of electrical appliances, the footprint is relatively high and the cost is prohibitively high, making it unsuitable for residential deployment.

Another problem associated with existing smart meters or smart distribution panels is the sensors adopted for obtaining voltage and/or current data. Sensors used for measuring current or voltage signals include the current and voltage transformer as well as hall-effect sensors which are relatively bulky and expensive.

In the arena of smart meters, FIG. 3 illustrates an example of a traditional DB-box that uses a common metal (e.g. copper, aluminium) conductor to aggregate the live (outgoing) or neutral (returning) wires from each current/circuit breaker branch and connect to the main live or neutral bus bar. The live wires are connected to the live bus bar first, and from the bus bar wires are divided or spilt to each MCB. Similarly for the neutral wire, the neutral wire of each current/MCB branch connects to the neutral bus bar, and the neutral bus bar connect to the main neutral wire. Existing solutions for measuring branch currents involve modification of wirings and/or are typically not space-efficient in part due to the measurement sensors deployed. Moreover, due to modifications made to the wiring configurations, technicians or engineers typically have to be re-trained or undergo some form of training to operate such smart meters.

In light of the drawbacks associated with each of the aforementioned solutions, there is exists a need for a relatively low cost, high resolution, low footprint and easy to deploy apparatus, system and method for energy management.

The invention seeks to address the aforementioned needs at least in part.

### SUMMARY OF THE INVENTION

Throughout the document, unless the context requires otherwise, the word “comprise” or variations such as “comprises” or “comprising”, will be understood to imply the inclusion of a stated integer or group of integers but not the exclusion of any other integer or group of integers.

Furthermore, throughout the specification, unless the context requires otherwise, the word “include” or variations such as “includes” or “including”, will be understood to imply the inclusion of a stated integer or group of integers but not the exclusion of any other integer or group of integers.

An aspect of the invention seeks to provide a cost and space efficient apparatus as well as a high resolution measurement apparatus for installation with a conventional electrical distribution board, also known as panel board, breaker panel or electric panel. Using the apparatus, the information of the distributed electricity received in the form of electronic data can be used to monitor and manage the energy consumption in one or more premises. The data received could further assist a user glean useful information related to other aspects like usage behaviour, safety and security.

In accordance with an aspect of the invention there is an apparatus for installation with an electrical distribution box comprising at least one bus bar and a plurality of circuit breakers, the apparatus comprising a sensor circuit comprising at least one sensor arranged in series connection with the bus bar and one of the plurality of circuit breakers, wherein one terminal of the at least one sensor is connected to the bus bar and another terminal of the at least one sensor is connected to one of the plurality of circuit breakers; wherein the apparatus further comprises a processor to obtain a corresponding voltage signal and a corresponding current signal flowing through the at least one sensor.

In some embodiments, the at least one sensor is a resistor, a hall-effect sensor or a current transformer.

In some embodiments, the bus bar is a live or neutral conductor plate.

In some embodiments, the processor operates to derive at least one power parameter based on the corresponding voltage signal and corresponding current signal obtained.

In some embodiments, the processor comprises at least one of the following: a signal processing unit having a voltage and current amplifier, a filter, and an analogue to digital converter (ADC). Where there are a plurality of sensors in the sensor circuit, a selector device may be positioned between the sensor circuit and the signal processing unit to toggle between inputs from each of the plurality of sensors fed to the signal processing unit.

In some embodiments, the sensor circuit comprises one sensor and a selector device operable to toggle the series connection between the one sensor and each of the plurality of circuit breakers.

In some embodiments, the at least one power parameter includes root mean square voltage, root mean square current, active power, reactive power, apparent power, power factor, frequency, harmonics profile.

In some embodiments, the sensor circuit and processor are mounted on a single circuit board. Alternatively, the sensor circuit is mounted on a first circuit board and the processor is mounted on a second circuit board, wherein the second circuit board comprises a short circuit protection circuit.

In some embodiments, the processor comprises a communication module.

In some embodiments, the communication module comprises a wireless transceiver arranged to send and receive data with a third party server.

In some embodiments, the at least one wireless transceiver is capable of supporting at least one of the following wireless communication protocols: ZigBee, Zwave, wireless mobile telecommunications.

In some embodiments, the apparatus is operable to switch between a first communication mode where the apparatus is configured as a client, and a second communication mode where the apparatus is configured as an application server.

In some embodiments, a system for energy management may be formed comprising an electrical distribution box installed with the apparatus, which in turn comprises the communication module, a server arranged in data communication with the apparatus to receive the obtained voltage, current data signal and at least one power parameter, wherein the electrical distribution box further comprises a detector to detect and establish a data communication link with the server.

In some embodiments, if the electrical distribution box is unable to establish a data communication link with the server after a predetermined number of retries, the data communication link is switched to a communication with a computer device.

In some embodiments, the distribution box comprises a real time clock module arranged to provide a time stamp for each voltage or current data signal.

In some embodiments, upon a power interruption or shutdown, the real time clock module is reset to a predetermined setting after power is restored and a flag indicating that time stamp correction is required is set.

In some embodiments, upon detection that time synchronization is available, the real time clock module is restored to the correct time and all affected time stamps are time shifted.

In accordance with another aspect of the invention there is a management system comprising an apparatus for installation with an electrical distribution box comprising at least one bus bar and a plurality of circuit breakers, the apparatus comprising a sensor circuit comprising at least one sensor arranged in series connection with the bus bar and one of the plurality of circuit breakers, wherein one terminal of the at least one sensor is connected to the bus bar and another terminal of the at least one sensor is connected to one of the plurality of circuit breakers; wherein the apparatus further comprises a processor to obtain a corresponding voltage signal and a corresponding current signal flowing through the at least one sensor, the apparatus arranged to receive a voltage dataset and a current dataset from a plurality of electrical load over a predetermined period; a load identification module operable to identify each of the plurality of electrical load based on the voltage and current dataset received; and an electrical appliance activity recognition module operable to extract at least two states of each electrical load over the predetermined period.

In some embodiments, the at least two states of each electrical load comprise two of the following states: operate, standby, stop.

In some embodiments, the sensor device is configured to derive at least one power parameter, the at least one power parameter includes active power, reactive power, apparent power, power factor, harmonics.

In some embodiments, the load identification module operates to identify an electrical load based on extraction of a plurality of signatures from the voltage and current dataset obtained over a predetermined period.

In some embodiments, the predetermined period is twenty-four hours.

In some embodiments, the plurality of signatures comprise zero current count, on-off cycle count, and maximum power consumption.

In some embodiments, the plurality of electrical load are classified based on a k-nearest neighbour algorithm.

In some embodiments, the system further comprises an energy consumption estimation module to receive past voltage dataset and current dataset for estimating a future period of energy consumption, the energy consumption module comprises at least one user interface suitable for customization by a user as to the level of granularity.

In some embodiments, the system further comprises an energy audit module wherein an operational state is extracted from the electrical appliance activity recognition module for calculation of at least two statistical parameters.

In some embodiments, the system further comprises a monitoring module operable to trigger data collection and activate the load identification module and the electrical appliance activity recognition module to convert the data.

In some embodiments, the system further comprises a safety module operable to receive thresholds of current and power rating and electronically notify a user once a threshold for current or power is exceeded.

In some embodiments, the system further comprises a lifestyle module operable to retrieve energy consumption data from the voltage and current dataset to derive an indication relating to a non-electrical energy consumption, electrical energy consumption relating to one type of electrical appliance, or electrical energy consumption relating to multiple electrical appliances within a location.

In accordance with another aspect of the invention there is a management system comprising at least one sensor arranged to receive a voltage dataset and a current dataset from a plurality of electrical appliances over a predetermined period;

a load identification module operable to identify each of the plurality of electrical appliances based on the voltage and current dataset received; and
an electrical appliance activity recognition module operable to extract at least two states of each electrical appliance over the predetermined period.

### BRIEF DESCRIPTION OF THE DRAWINGS

The present invention will now be described, by way of example only, with reference to the accompanying drawings, in which:

FIG. 1 is a system diagram of some embodiments of the invention illustrating a distribution board, a computer device and a storage and analysis platform.

FIG. 2 shows a layout of the apparatus for installation with an electrical box according to some embodiments.

FIG. 3 shows a prior art layout of a traditional distribution box.

FIG. 4 shows a splitter circuit in accordance with an embodiment of the invention.

FIG. 5a and FIG. 5b illustrate the analogue front end and analogue to digital (ADC) signal processing circuit in accordance with some embodiments of the invention.

FIG. 6a and FIG. 6b illustrate two different configurations where the apparatus (or an electrical distribution box installed with the apparatus) can establish communication with third party devices.

FIG. 7 is a flow chart that illustrates a method of automatic switching between the two different configurations of FIG. 6.

FIG. 8 illustrates an embodiment of how multiple devices may communicate with one another.

FIG. 9 illustrates a method where the RTCC module auto-synchronizes and corrects any erroneous time stamp(s) arising from a power interruption.

FIG. 10 illustrates a system for energy management in accordance with some embodiments of the invention.

FIG. 11a to FIG. 11c illustrates the load model building and load identification methods in accordance with some embodiments of the invention.

FIG. 12a and FIG. 12b illustrates the appliance or activity model building and recognition methods in accordance with some embodiments of the invention.

FIG. 13 illustrates a method to activate data collection and conversion in accordance with some embodiments of the invention.

FIG. 14 illustrates a method of safety monitoring in accordance with some embodiments of the invention.

FIG. 15 illustrates an example of how a system for energy management may be utilized to monitor sleeping patterns in accordance with some embodiments of the invention.

Other arrangements of the invention are possible and, consequently, the accompanying drawing is not to be understood as superseding the generality of the preceding description of the invention.

### EMBODIMENTS OF THE INVENTION

Particular embodiments of the present invention will now be described with reference to the accompanying drawings. The terminology used herein is for the purpose of describing particular embodiments only and is not intended to limit the scope of the present invention. Additionally, unless defined otherwise, all technical and scientific terms used herein have the same meanings as commonly understood by one of ordinary skill in the art to which this invention belongs.

In accordance with an aspect of the invention there is an apparatus 100 for installation with an electrical distribution box 10. The electrical distribution box typically comprises bus bar for live, neutral and ground and a plurality of branches for distribution to various electrical sockets in a premise. Each branch is installed/equipped with one or more circuit breakers 20 before distribution to the power sockets where load or electrical appliances can be plugged into. It is to be appreciated that the term ‘load’ or ‘electrical load’ may comprise one or more electrical appliances. It is to be appreciated that the circuit breakers 20 may be utilized for different functions including for isolation and protection, and may include different types of circuit breakers such as, but not limited to Miniature Circuit Breaker (MCB) and Residual Current Circuit Breaker (RCCB).

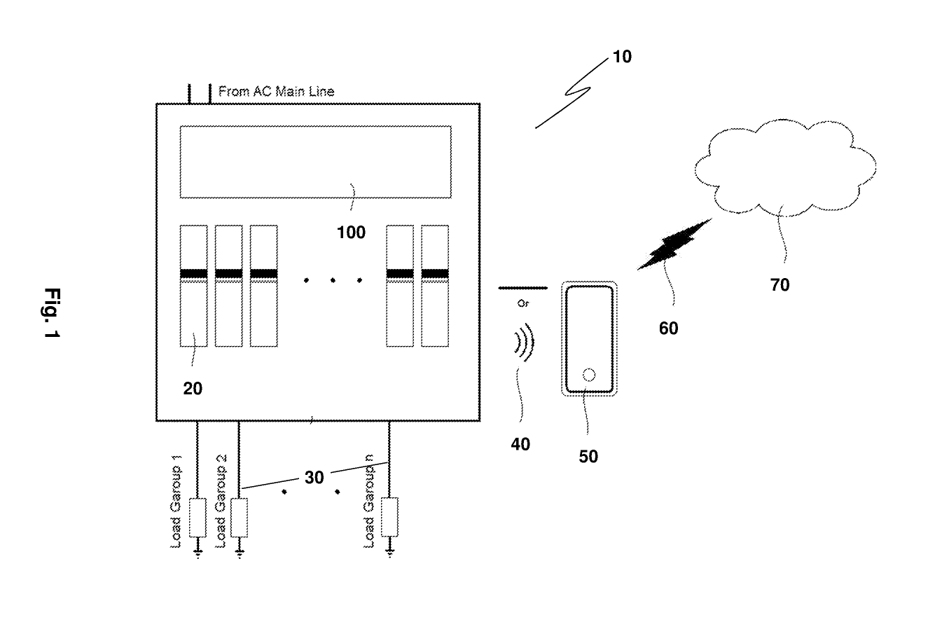

In various embodiments as illustrated in FIG. 1, the apparatus 100 is installed within the electrical distribution box 10. The electrical distribution box 10 may be a smart distribution box which operates to collect electrical power data from the electrical appliances and arranged in data communication with a computer device 50 or a server 70 for performing analysis relating to power consumption of each load or electrical appliance. The data communication is enabled by communication means such as communication devices 40, 60 which are based on wired or wireless communication protocols.

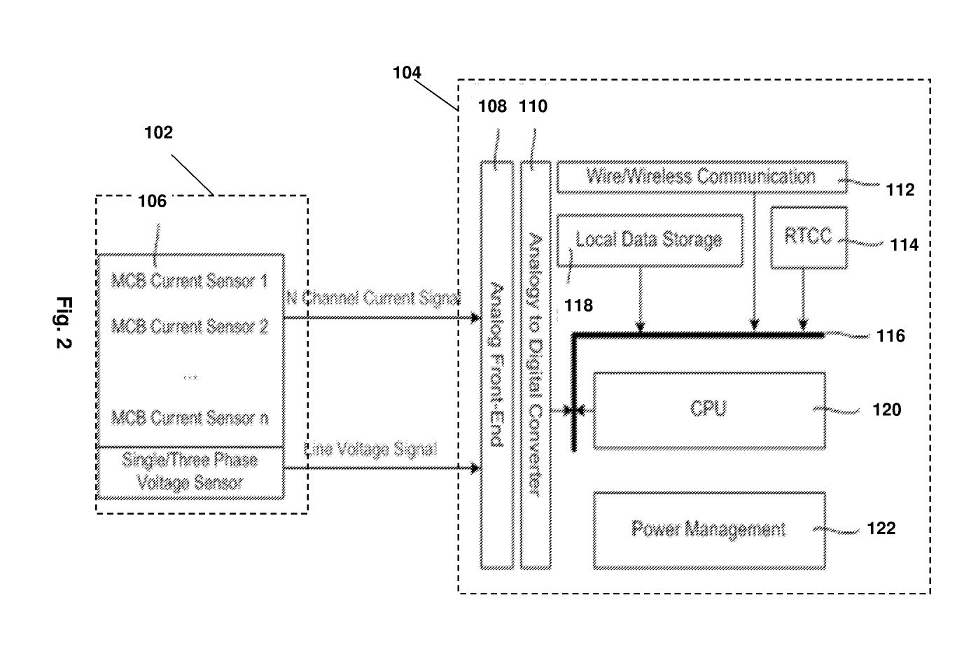

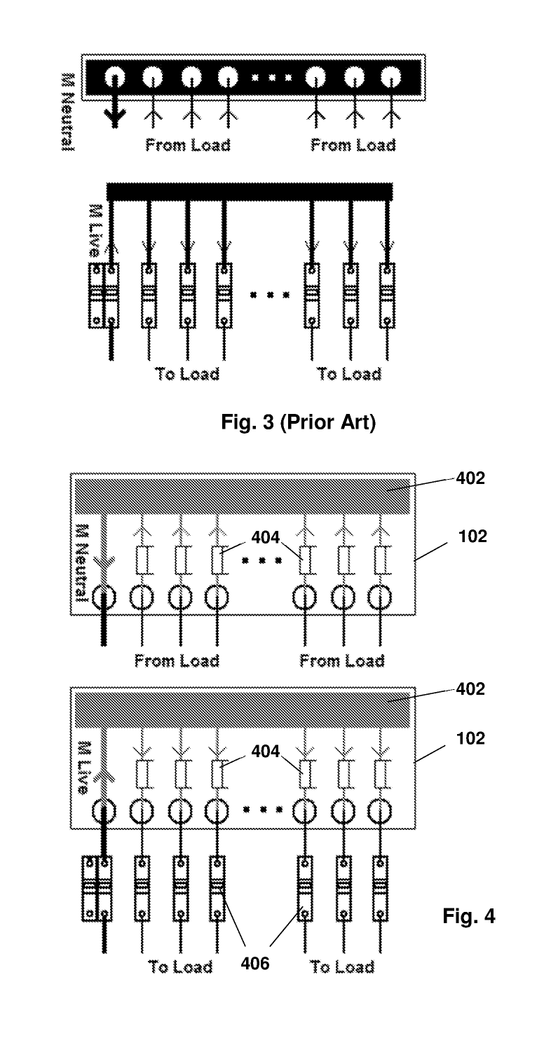

FIG. 2 shows a block diagram of the apparatus 100 which comprises a sensor circuit 102 and a processor 104. The sensor circuit 102 may comprise different sensors for obtaining electrical parameters such as voltage and current signals, and non-electrical parameters such as temperature via temperature sensors. The obtained parameters (in the form of electronic data) may be stored and processed by the processor 104 in a local data storage, or stored externally to any third party servers or devices such as computer device 50 or server 70. The processor 104 includes an analogue front end (AFE) 108, an analogue-to-digital converter (ADC) 110, a communication module 112, a real time clock/calendar module 114, a communication bus 116, a local data storage medium 118, a processor, such as a micro-controller 120, and a power management module. The processor 104 is arranged to obtain a corresponding voltage signal and a corresponding current signal from the sensor circuit 102 across the at least one sensor to derive at least one power parameter.

Embodiments of the individual components will be described with reference to FIG. 4 to FIG. 8.

With reference to FIG. 4, an embodiment of the sensor circuit 102 comprises a plurality of electrical current sensors 404 deployed at each distribution branch (hereinafter referred to as channel) of the electrical distribution box. Each channel may correspond to an electrical socket, an electrical load or a plurality of electronic load. In some embodiments, each channel can correspond to one electrical appliance or an electrical socket with power extension strips capable of supporting a number of electrical appliances such as TV, WiFi box, computer etc.). Each current sensor 404 is arranged in a series connection with respect to a live or neutral bus bar 402 and with one of the plurality of circuit breakers 406, wherein one terminal of the at least one sensor 404 is connected to the bus bar 402 and another terminal of the at least one sensor is connected to one of the plurality of circuit breakers 406. In some embodiments, the sensor circuit 102 may comprise additional bar bars for connection or superimposition onto existing bus bar of the electrical distribution box 10.

The arrangement, also referred to as ‘split conductor’ technology, is utilized where the live or neutral metal conductor (bus bar) is designed to separate each branch current path (with circuit breaker such as MCB) for the current passing through each MCB to be measured. As shown in FIG. 4, there comprises a plurality of current sensors, each current sensor may be a passive sensor, and may be in the form of a resistor which has a resistance value R_{b} arranged in series in each branch path. By measuring the voltage drop, V_{b}, of each series resistor, the current, I_{b}, of each branch can be calculated using Ohm's Law (i.e., I_{b}=V_{b}/R_{b}). The series resistor can therefore be introduced by physical connection of a resistor in series with the wiring or integrated with the processor 104 via a print circuit board (PCB).

In some embodiments, instead of resistor sensors, other types of sensors suitable for a series arrangement with the MCB and bus bar may be utilized. These sensors may include hall-effect sensors and current transformers.

In some embodiments, instead of using multiple sensors, there may comprise one sensor resistor permanently hardwired with the neutral or live bus bar. A selector device, such as a multiplexer chip (not shown), may then be connected in series with the sensor resistor. The multiplexer chip may then be configured by a controller to effect a series connection with each circuit breaker branch for a predetermined period or logic.

In an alternative embodiment, a multiplexer chip may be positioned between the sensor circuit 102 and processor 104. In the embodiment, the multiplexer chip may be positioned to receive input from the plurality of sensors in the sensor circuit 102. Such an arrangement enables one single set of analogue front end (AFE) 108 and analogue-to-digital converter (ADC) 110 to be utilized to receive multiple signals flowing through the multiple sensors thereby reducing the overall size and manufacturing cost of the apparatus 100.

In choosing the sensor resistor, the temperature coefficient of resistance of the series sensor (resistor) must be taken into consideration as the resistance of the series sensor changes when the temperature increases. A proper value of the series sensor and the thermal design are needed to reduce the effect of temperature

on the resistance. Generally, a small resistance of the series sensor will reduce the temperature rise during the operation however the amplitude of voltage signal which is generated by the series sensor will be correspondingly low.

In particular, the choice of resistance values is based on the following principle:—

a. The heat loss of the resistors depends on the current and the resistance of the sensor based on the Ohm's law. Generally, the heat loss of each sensor could be controlled and is limited to less than two watts.
b. A small value of resistance will reduce heat loss, but with resulting decrease in signal-to-noise ratio. Care is taken to reduce noise interference and resistance fluctuations taking into account temperature, soldering quality, PCB board quality, aging and others parameters.

In some embodiments, the sensor circuit 102 is implemented as a circuit board such as, but not limited to a printed circuit board (PCB), Vero board etc. In the embodiments where PCB is used, the conducting tracks of the PCB are arranged such that the connection of all the wires and a resistor (as the series sensor) of fixed resistance are connected by the PCB track. Further, the sensor circuit may comprise conducting strips to reduce or overlay the original bus bar found in the electrical distribution box 10. With the PCB as an add-on module which can be nearly ‘plug and play’, the apparatus avoids many modifications which may include changing the wiring logic and/or pattern of the wiring metal bar. Such an arrangement seeks to ensure that the entire installation process (including internal wiring) of an electrical distribution installed with the apparatus (hereinafter referred to as Smart-DB box) and a conventional Distribution Board is comparable, hence avoiding re-training of qualified personnel (technicians and engineers).

The deployment of resistors as series sensors provides a relatively simple structure that enhances the form factor of the apparatus 100. It will also reduce the space compared with other measurement method (e.g. current transformer).

In some embodiments, the sensor circuit 102 and the processor 104 may be implemented as separate PCBs. Short circuit protection circuit may be implemented on the sensor circuit 102 such that the normal functions of the distribution box 10 will still be available when the processor 104 of the apparatus 100 is malfunctioned due to various circumstances (E.g. Lightning, dust, and short circuit). The short circuit protection circuit may also be implemented on the processor 104.

Turning to the processor 104, upon receipt of a current signal and line voltage signal from one or more current sensors, the AFE 108 comprises a set of analogue signal conditioning circuitry that uses sensitive analogue amplifiers, often operational amplifiers, filters, or sometimes application-specific integrated circuits (ASIC) to receive the voltage and current signal generated to provide a configurable and flexible electronics functional block, needed to interface the current/voltage sensor to an analogue to digital converter (ADC) or in some cases to a microcontroller (CPU).

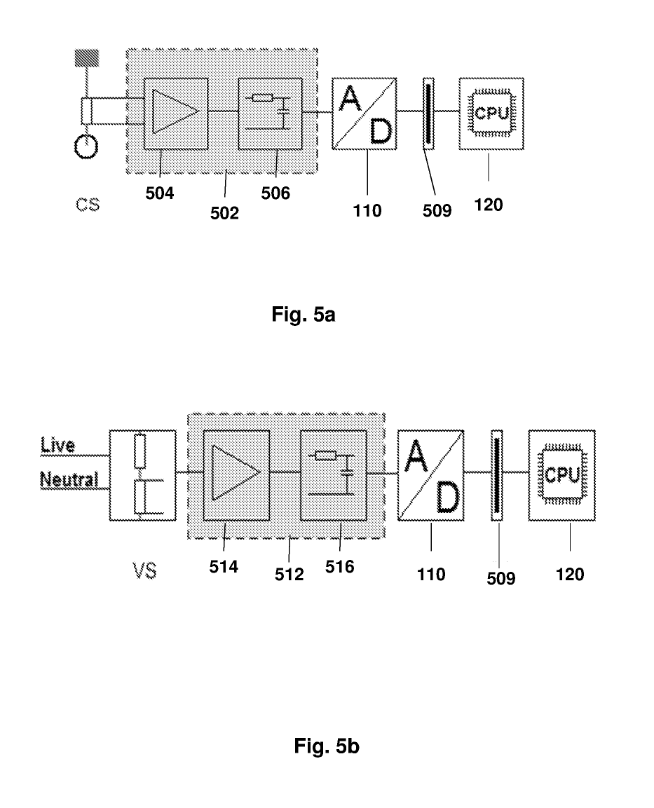

In the embodiments as shown in FIGS. 5a and 5b, the current/voltage signal sensed by the corresponding series resistor will be amplified by an amplifier circuit 502/512 comprising an operational amplifier 504/514. Another function of the operational amplifier 504/514 is to shift the current/voltage signal from an AC signal (negative and positive) to a pure positive signal which can be used by a normal ADC (analogue to digital converter).

Any amplified voltage signal is connected to a filter circuit 516 which is used to remove noise that may be superimposed by the AC power line or the metal conductor or the operational amplifier 504/514. Instead of a physical filter circuit, a digital signal processer may be a functional equivalent. The at least one derived power parameter may include real power, reactive power, power factor and line frequency. To derive these parameters, the line voltage is needed. The supply line voltage (usually 240 VAC/100 VAC) is stepped down to a low level voltage signal by a voltage transmitter (It can be achieved by a sample voltage divider, or a small voltage transformer, or a liner optical isolator).

The clean signal which is the output of the AFE 108 is sent to the ADC 110. The analogue signal is converted to a quantized digital value which will be further processed by the microcontroller 120 which functions as a central processing unit (CPU). In some embodiments, isolation circuits 509/519 are utilized to improve safety and to protect the CPU 120 from damage arising from sudden current/power surge. The communication module 112 serves to provide data communication between the electrical distribution box 10 installed with the apparatus 100 and third party devices. In some embodiments the communication module 112 comprises wired and wireless adapters and transceiver for data communication based on different communication protocols or technology. Such communication technology used include and is not limited to Ethernet, RS232, W-Fi, ZigBee, ZWave, GSM/3G/4G technologies or a combination of such technologies.

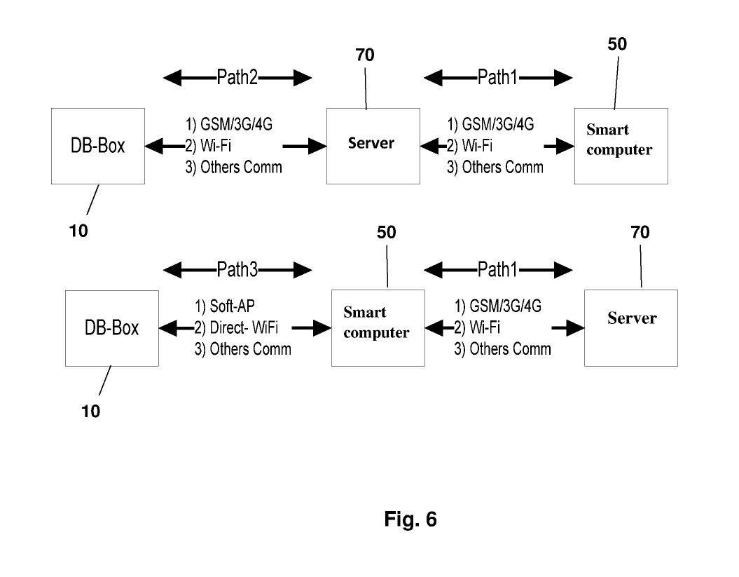

The communication module 112 may comprise one or more network detectors installed to detect and establish communication link between the module 112 and computer device 50 or server 70. Depending on the type of device or communication network, the electrical distribution box 10 may function as a client or a server. As illustrated in FIG. 6a, when a communication link is established with the server 70, the communication module 112 is configured as a client and data and information from the electrical distribution box 10 is sent to the server 70 using for example mobile data network, Wi-Fi or other communication protocol (see Path 2). In such arrangement, a cloud service and an internet service, may be required. A real-time DB-Box data analysis algorithm can be deployed on the server 70, which, in some embodiments, can be a cloud server. The operation mode is mostly used for some urgent event detection function (House security checking, life state prediction or abnormal state monitoring). In this mode, the computer device 50 is an optional device and can receive data from the server 70 through a normal public network (Path 1). Where computer device 50 is a smart phone or mobile tablet device, dedicated software applications (colloquially referred to as ‘apps’) may be installed for communication with the server via push/pull technologies.

Where real-time connection to the server 70 cannot be established, the smart DB-box 10 is configured as a soft application server and communicates via short range communication such as, but not limited to, direct Wi-Fi, Bluetooth, and Bluetooth LE etc. The smart DB-Box 10 stores the monitoring data in the local storage module 118 and it is configured by the CPU to initiate communication and transfer the data at a fixed time point of each period (E.g. 12:00 PM to 12:30 PM). The smart device (E.g. Smart Phone, Smart Gateway) is configured (via apps or otherwise) to automatically connect to the DB-Box W-Fi network (Path 3) at per-defined time slot, and the DB-Box box data will be fetched by the smart device. This function will be used for some no-critical state prediction function (E.g. power utilization pattern detection, next month power utilization prediction or appliances lifetime prediction). The data fetched by the smart device may then be sent by to the server 70 by the smart device 50 when a public network is available. In some embodiments, the smart device functions as a ‘relay’ or ‘assistive’ device to relay data to the server 70.

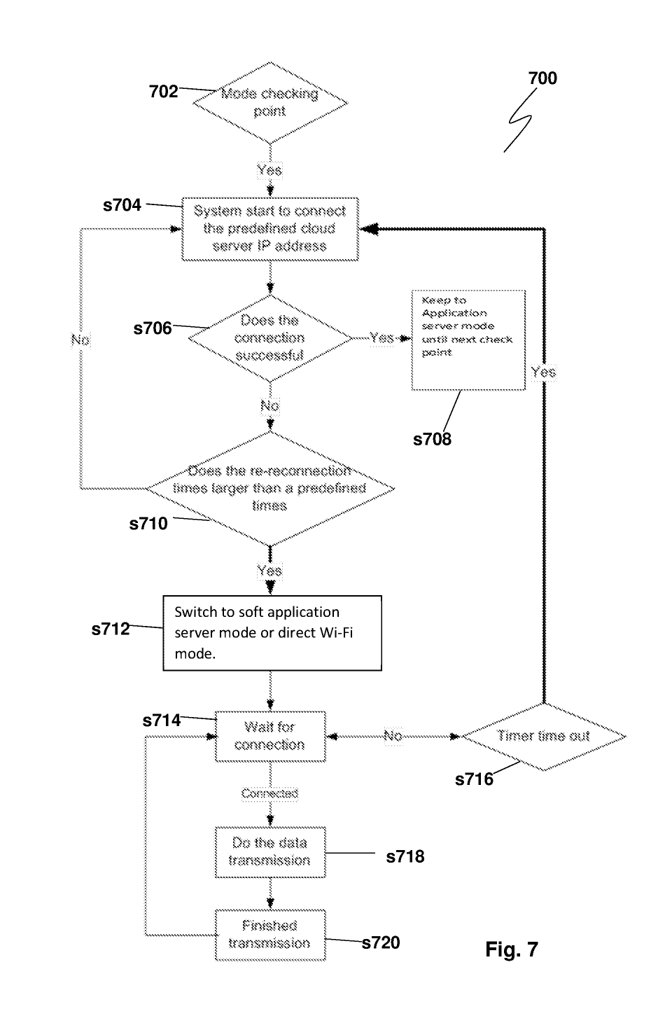

In operation, the communication link between the smart DB-box 10 and the server 70 may not always be reliable or consistent. For example, cloud service and the internet service may not available. To mitigate the need for a manual toggling, a method of automatically switching between the client mode and application server mode 700 is developed for the smart DB-Box 10. The flow chart is shown in FIG. 7.

The method begins with a mode checking step s702 for determining which mode the smart DB-box 10 is at. Regardless, it will be reset to ‘client mode’ to establish a data communication link with the server 70. At step s704 the smart DB-box 10 attempts to establish the data communication link based on for example an IP address of the server 70. At decision step s706 the smart DB-box checks if the communication link is successfully established. If the communication link is successfully established, the data transmission is made step s718.

If the communication link with the server 70 is not established, a next decision step s710 is checked (against a software counter or and/flag) if the re-connection number of times is larger than a predefined number (for example three-five times). If the re-connection number is not larger than a predefined number, the method loops back to s704 and attempts to re-connect.

If the re-connection number is larger than the predefined number, then the communication mode is switched to the ‘soft application server’ mode or direct Wi-Fi mode (step s712). Connection is then initiated and attempted with the computer device 50 (step s714). If no connection is established within certain predetermined timer time out (step s716), the method loops back to step s704. If a communication link is established, the data transmission can then take place according to step s718. Once the present data transmission is completed (step s720) the method loops to step s714 wait for connection. When all data transmission is completed, the method loops back to step s70 to determine which mode the smart DB-box 10 is operation at.

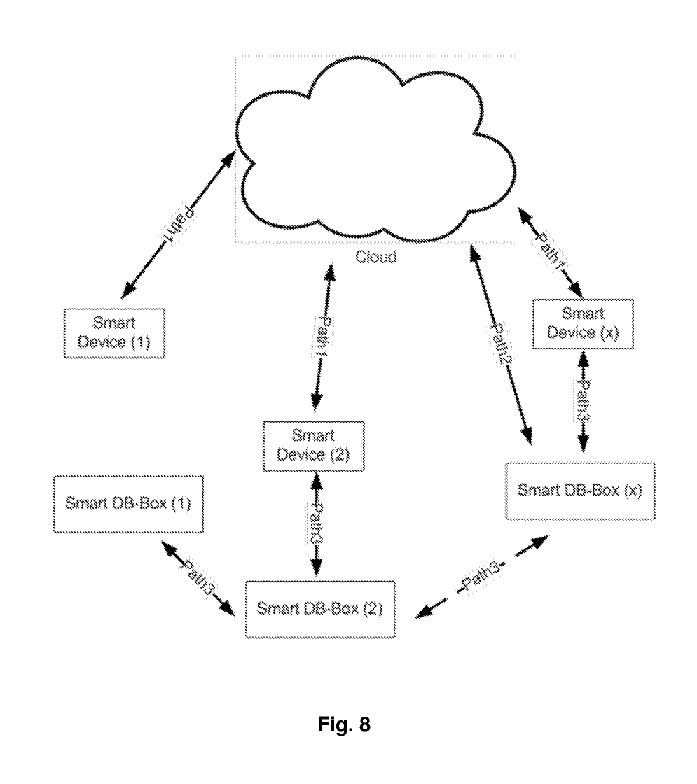

In some embodiments, the smart DB-box 10 may communicate with other smart DB box 10. In these embodiments, one of the DB-box 10 may be configured as a soft application server and the other smart DB-box the client. FIG. 8 shows how different devices may interact with one another to transmit data between the server 70, the computer device 50 and the smart DB-box 10.

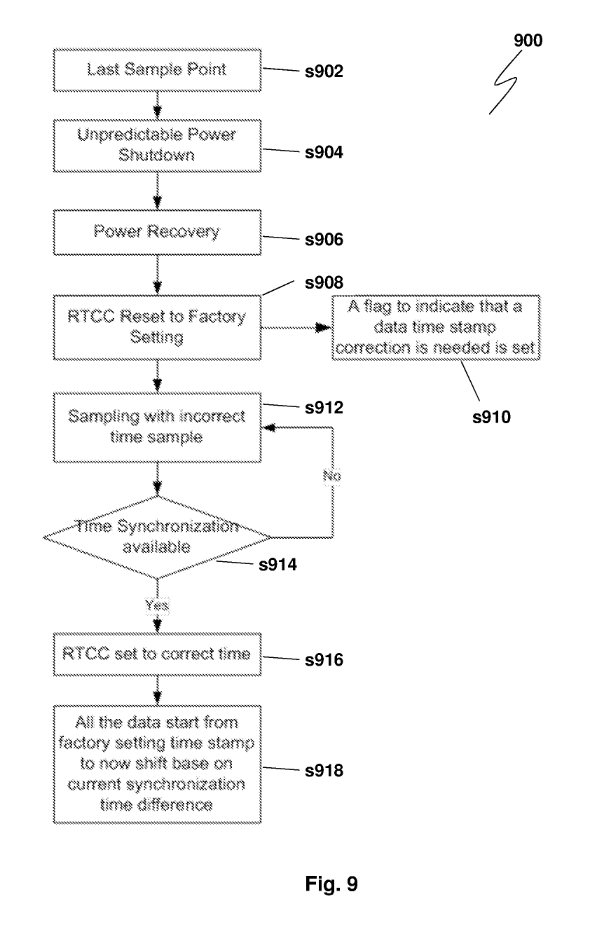

The real time clock and calendar (RTCC) module 114 may be integrated with the CPU 120 or may be an independent integrated circuit chip. The RTCC 114 is used to generate the time stamp of each data point received and may also be used to generate clock cycles for any other applications and/or module. In some embodiments, the synchronization of RTCC is performed when the smart DB-box 10 is connected to the server 70 or computer device 50. An external battery may be required to maintain the RTCC's operation when electricity (AC power) is not available. However, in some embodiments, an external or additional battery may be omitted, thus further reducing form factor of the apparatus. In the event where electricity is not available, the RTCC time will be reset to the pre-defined time after power is recovered. Once a connection is established with the central server 70 either via a computer device 50 or otherwise, the RTCC will synchronize the correct time. The sensor data which was received during the power interruption will be corrected in accordance with the flowchart of FIG. 9. With reference to FIG. 9, a method for auto-synchronization 900 commences at a last sample point (step s902) when an unpredictable power shutdown is detected (step s904). Upon power recovery at step s906, the RTCC is reset to a factory setting (step s908). A flag to indicate that a data time stamp collection is needed is set (step s910). This flag corresponds to the first sampled data after power recovery. Sampling of data then continues after power recovery based on the factory setting (step s912). When time synchronization becomes available via an establishment to the server 70 or computer device 50 (step s914), the RTCC is set to the correct time (step s916). All the data sampled after power recovery which is based on the factory setting will be time shifted to the actual synchronized time difference at step s918, beginning with the last sampled data before synchronization. The time shifting process will stop at the first sampled data after power recovery.

The on-board communication bus 116 is a platform linking all the various module together. The communication bus 116 may comprise an Inter-Integrated Circuit (I2C), Universal asynchronous receiver/transmitter (UART), Serial Peripheral Interface (SPI), and Controller Area Network (CAN).

The local data storage module 118 may be a non-volatile memory that includes Electrically Erasable Programmable Read-Only Memory (EEPROM), Flash memory, SD/micro-SD card etc. It can be used to store any data and information. All received voltage and current data may be time stamped and stored in the local storage. In some embodiments, a data packet that is to be transferred can be broken into smaller data packets. At any point in time, the system will transfer one of the smaller data packet. That smaller data packet will only be discarded by the Smart DB, if the Smart DB has received an acknowledgment that the smaller data packet has been successfully received from the target device (e.g. the computer device 50). If an unstable network causes an interruption of the transmission, the smart DB cannot receive the acknowledgement signal from the target device. The smart DB will restart the transfer process of the smaller data packet when the network is next made available.

The power supply management module 122 operates to manage and provide power for the micro-controller 120 and other modules. In some embodiments, two or more isolated power sources can be used to prevent signal cross-talk between high and low voltage circuits.

The communication network 40, 60 may be any type of network to facilitate the establishment of data communication between the various devices, including public networks.

The obtained electronic data may be encrypted or protected by other methods to provide authorized access and protect against unauthorized access.

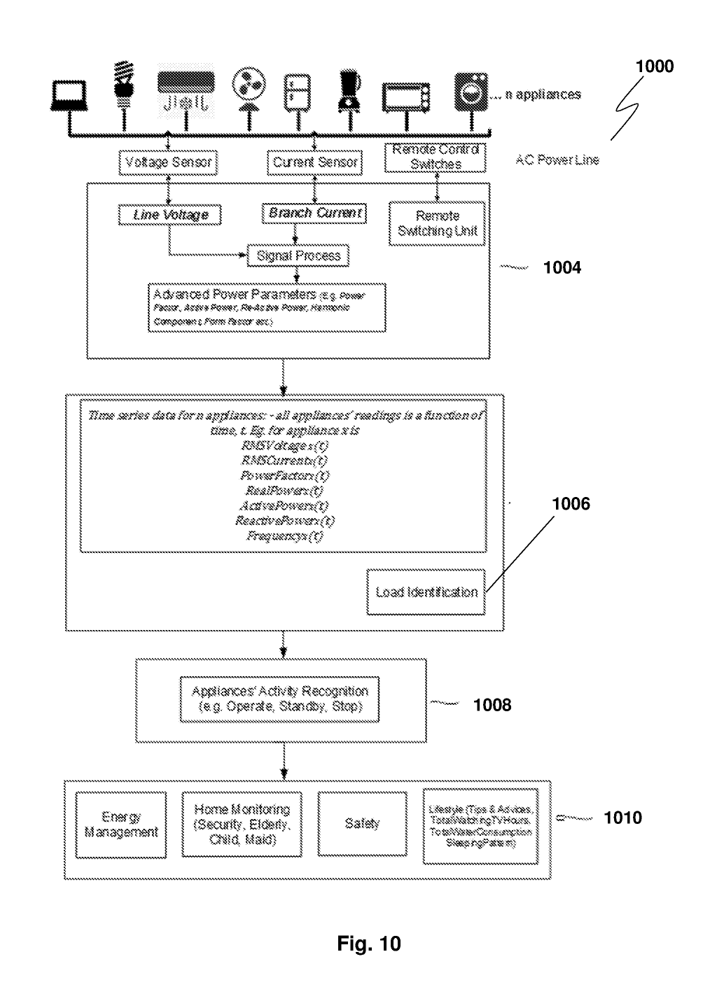

In accordance with another aspect of the invention there is a system for energy management 1000 as shown in FIG. 10. The system may comprise at least one smart electrical distribution box 10 installed with at least one or a plurality of voltage/current sensors as described in the earlier embodiments, or any other smart distribution box or sensors capable of retrieving data relating to electrical appliances usage and communicate said data to one or more servers for analysis. The system 1000 is suitable for deployment in a residential premise. In the description of the system 1000, each ‘channel’ may be understood to refer to an electrical socket or a group of electrical sockets supplied by a particular branch current MCB from the electrical distribution box.

The one or more servers may be arranged in data communication with the apparatus 100 to receive the time series data. The time series data may comprise instantaneous voltage, instantaneous current from each current branch. At least one parameter associated with electrical power usage such as power factor, active power, re-active power, harmonic component, frequency may be derived from the time series data.

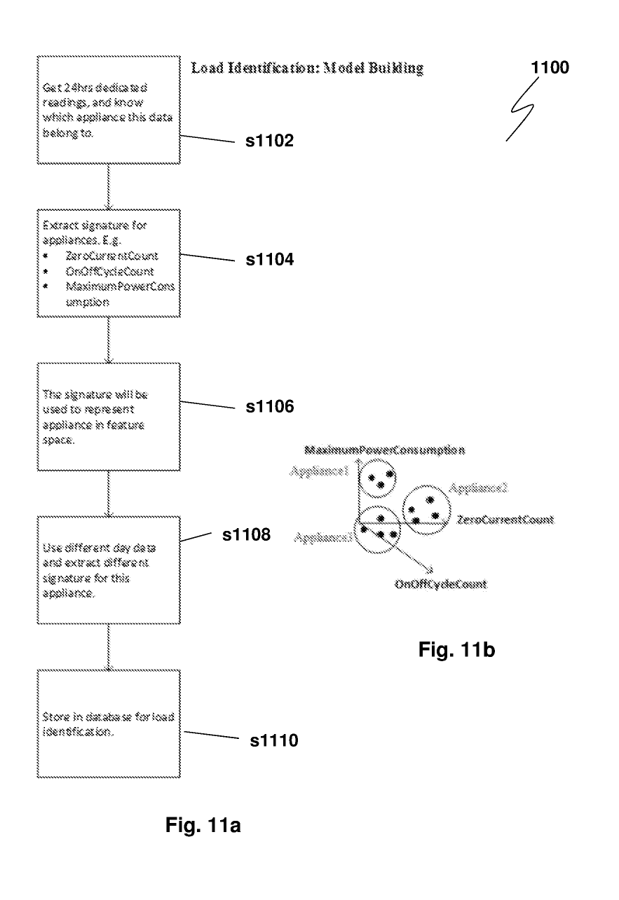

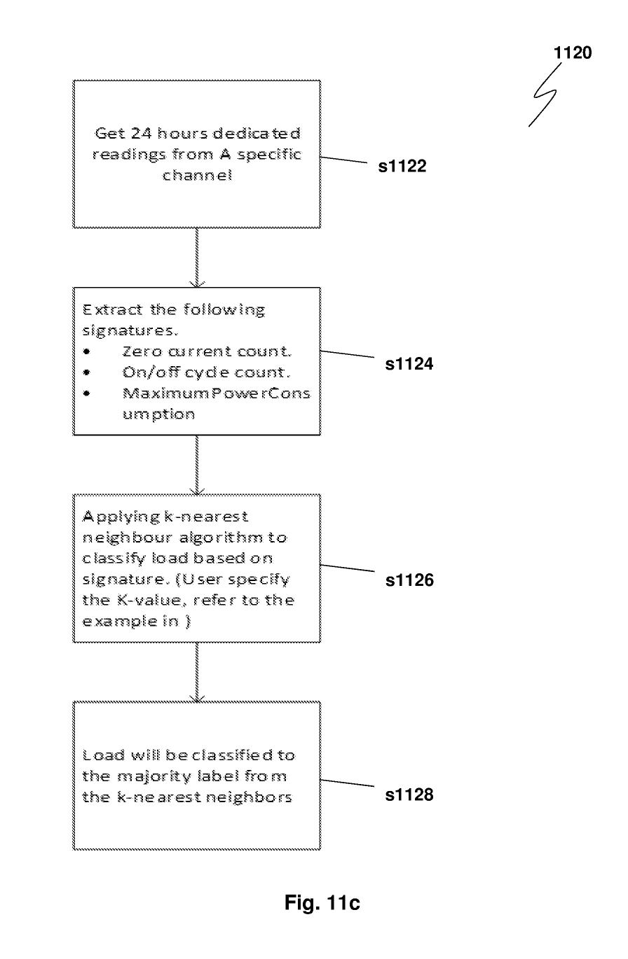

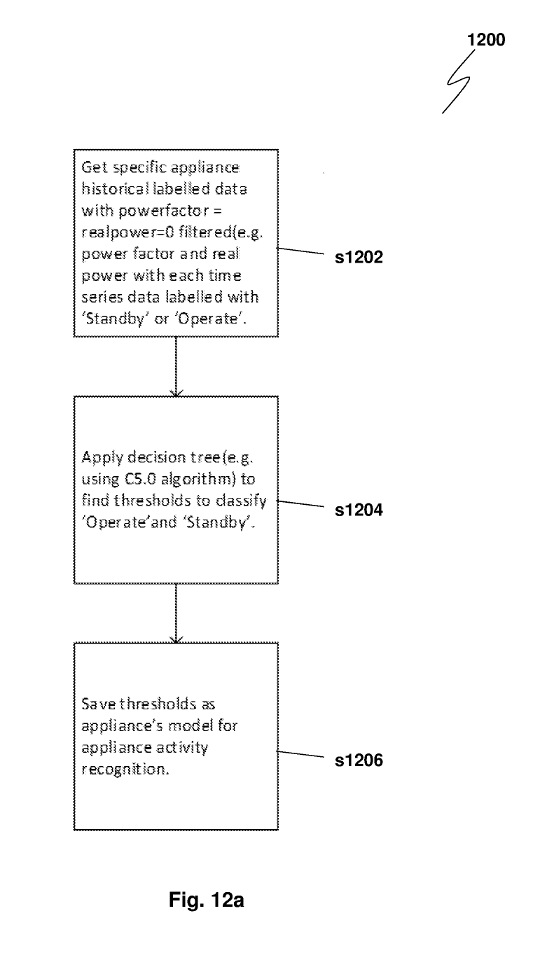

In the embodiment with reference to FIG. 10, the system comprises one or a plurality of voltage and/or current sensors 1004 operable to obtain voltage and current data from a plurality of electrical appliances. These sensors 1004 may be installed with the smart electrical distribution box 10 or may be other types of smart sensors or meters installed at individual power sockets. Electrical power parameters such as power factor, active power, re-active power, harmonic component, frequency may be derived. In some embodiments, temperature or other non-electrical sensors may be deployed. The data obtained from the sensors 1004 are then output to a load identification module 1006 to differentiate between the various electrical appliances or electrical load should the need arise. The load identification module 1006 comprises a processor server (distributed or otherwise) arranged to receive the data obtained from the sensors 1004 and execute a load identification method 1120 for distinguishing at least one type of electrical load from another. In some embodiments instead of a processor server there may be a processing module capable of fulfilling processing functions. Databases may be arranged in data communication with the load identification module 1006 for storage of data. Referring to FIG. 11a to 11c, before the load identification method 1120 is executed, a model building method 1100 (reference FIG. 11a) using training data from known loads is performed. The model building method comprises obtaining one or more dataset with known identity for a predetermined period, for example twenty-four hours—see step s1102.

The values of a predefined plurality of features/signature are then extracted (step s1104) from the dataset. These values are used to distinguish one type of electrical load from another. Examples of the signatures include:

a. zero current count: the number of zero current occurrences within the predetermined period, i.e. when load or electrical appliance is switched off or whenever current is zero or near zero (i.e. within certain predetermined tolerance) it will be counted as one occurrence;
b. on-off cycle count: the number of pairs of rapidly increasing and rapidly decreasing real power readings. Regardless of successive increasing value, the first increasing value until the next decreasing value is considered as one cycle count;
c. Maximum power consumption: the maximum real power reading obtained from the dataset.

The identified signature will be utilized for identification of the appliance in feature space (step s1106).

For improved accuracy, steps s1102, s1104 and s1106 may be repeated on another predetermined period to extract different signatures for the appliance (step s1108). The obtained signatures are then stored in the load identification module 1006 for use in the load identification method 1120.

The load identification method 1120 is executed by obtaining a dataset from a specific channel (current/MCB branch) for a predetermined period—step s1122. The signatures are then extracted (step s1124) and classified based on a k-nearest neighbour algorithm (step s1126 and s1128).

In some embodiments involving the usage of smart electrical sockets and smart electrical plugs in a premise, the load identification module 1006 may be incorporated or integrated within the smart electrical sockets or plugs.

The data obtained from the plurality of sensors 1004 (whether load identified or not) may be sent to an appliance activity recognition module 1008. The appliance activity recognition module 1008 may be a processor server (or a processing module) which comprises software codes installed thereon for executing a model building method 1200 and an activity recognition method 1220 to classify the appliance activity as one or more types of activity including, but not limited to ‘Operate’, ‘Standby’ or ‘Stop’.

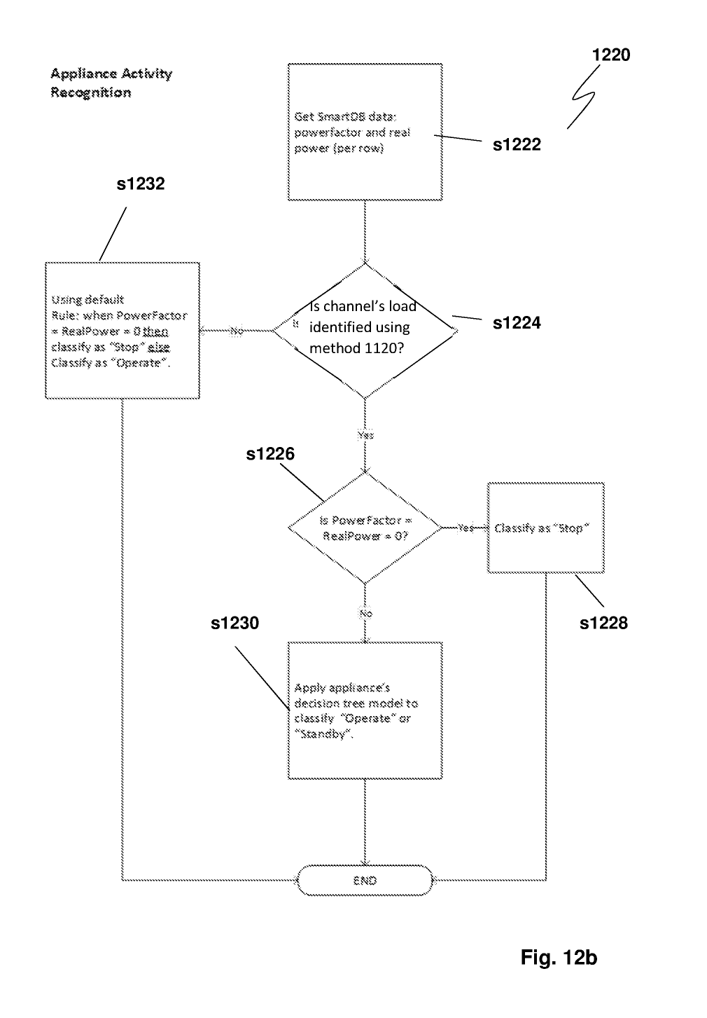

Referring to FIGS. 12a and 12b, the model building method 1200 involves the step of obtaining a training dataset which relates to a specific appliance or load's historical data with zero power factor and zero real power data filtered (which should be classified as ‘Stop’ straight away’) but instead of ‘stop’ these are labelled as ‘operate’ or ‘standby’—step s1202. A classification algorithm based on binary classification ad decision tree is next applied to identify thresholds for classification of ‘operate’ and ‘standby’—step s1204. The thresholds are then saved in one or more databases (step s1206) for use in the activity recognition method 1220.

An example of the classification algorithm is shown in Table 1 below. The table of training samples x1—current and x2—power factor, as well as their corresponding classification, are supplied to the decision tree algorithm for training.

TABLE 1
Training samples for classification of standby or operate mode

| Current (x1) | Power Factor (x2) | Label |
|---|---|---|
| 0.0030 | 0.4000 | Standby |
| 0.0040 | 0.8700 | Standby |
| 0.0040 | 0.8600 | Standby |
| 0.0040 | 0.8700 | Standby |
| 0.0020 | 0 | Standby |
| 0.0020 | 0 | Standby |
| 0.0020 | 0 | Standby |
| 0.0020 | 0 | Standby |
| 0.0020 | 0 | Standby |
| 0.0020 | 0 | Standby |
| 0.2520 | 0.5000 | Operate |
| 0.2530 | 0.5000 | Operate |
| 0.2540 | 0.5000 | Operate |
| 0.2550 | 0.5000 | Operate |
| 0.2550 | 0.5000 | Operate |
| 0.4810 | 0.5200 | Operate |
| 0.4890 | 0.5300 | Operate |
| 0.2300 | 0.9800 | Operate |
| 0.2310 | 0.9800 | Operate |
| 0.4390 | 0.8000 | Operate |

Based on the obtained decision tree, if x1<0.117, a data point will be classified as ‘standby’. Otherwise if x1≥0.117, then the data point will be classified as ‘operate’. It is to be appreciated that in the example, the generated decision tree does not require x2: power factor, to successfully classify the samples according to the labels. But considering more and much complex training samples will be utilized for training in real case, it is essentially to keep x2 as another dimension of information for classification. The activity recognition method 1220 commences with the step s1222 of obtaining selected data from the sensors or smart electrical distribution box 10. A step s1224 is made to find out if the load has been identified using the load identification method 1120. If yes, the method proceeds to check if the power factor and real power are zero (step s1226), and if yes, the activity for the specific appliance in relation to the selected data is classified as ‘stop’ or not in operation (step s1228). If the value of either the power factor or real power is not zero, the binary classification and decision tree is applied to classify ‘operate’ or ‘standby’ (step s1230).

If the load has not been identified at step s1224, then a default rule indicating that when the values of the power factor and real power are zero, the activity is classified as ‘stop’. Otherwise, it is classified as ‘operate’ (step s1232).

In summary, the load identification module together with the activity recognition module provide higher levels of identification instead of merely ‘stop/off’, or ‘operate/on’. It is to be appreciated that load identification is not necessarily for appliance activity recognition. However, because different electrical appliances has different electrical ‘signatures’ such as current and power factor thresholds for ‘standby’ recognition, load identification may be utilized in order to choose the correct thresholds for identification of an electrical appliance's activity.

The obtained processed data relating to load and activity profile may form the input for further analysis to provide energy management, energy monitoring or other management related data to one or more users. To achieve the energy management objective, the system 1000 may further comprise an energy management module 1010 that comprises one or more interface for users to input and interact with the system 1000. In some embodiments, such interface may be provisioned in the form of dedicated software applications for installation on one or more users' smart devices. The interface may comprise a standby power interface where classification of operate, standby and stop appliance energy readings and standby power may be displayed and highlighted to a user so as to provide an indication of the appliances' inactive usage cost. The interface may also comprise a power consumption interface where real time or historical energy usage may be displayed and the user may also retrieve data relating to one specific electrical appliance and reports may be generated to notify a user on whether any electrical appliance(s) have been switched on inadvertently.

A user may customise and build his energy consumption profiles via the interface. He or she may wish to analyse his energy consumption on a weekday, weekend, a full day at home or a full day away (e.g. vacation). To this end, different colour scheme may be used and the system can provide various options for the user to customize and label. In some embodiments, the system may calculate the average, mean or median energy consumption according to the user's classification (e.g. average energy consumption on a weekday for a particular month).

In some embodiments the system 1000 may provide one or more forecasting tool(s) based on historical data for a user to estimate his upcoming month of energy consumption. This may help a user manage his electricity bill or finances for the upcoming month. A possible formulation of estimation would be the summation of the following:

a. multiply the number of weekdays in a month with the weekday average energy consumption for the past month;
b. multiply the number of weekends in a month with the weekend average energy consumption for the past month.

In addition to differentiating by weekdays or weekends, a finer granularity taking into account specific days (e.g. full day away, full day at home) may be obtained for estimation but these days will have to be removed from either the number of weekdays or weekends to avoid double counting.

In some embodiments, statistical parameters, which includes average and standard deviation of an appliance's standby time, operational time, or switch off time may be obtained for a variety of purposes. One particular purpose is that for an energy audit. In some embodiments, certain level of customization for energy audit is provided to a user. The user may, via the user interface provided, specify dates, times and how frequent the energy audit is to be performed. The user may further specify the reporting sensitivity in terms of the number of standard deviations, for example.

In some embodiments, an electrical appliance's efficiency profile may need to be established before the energy audit is carried out. Such efficiency profile may be obtained using the activity recognition method 1220, wherein the operational duration of the appliance corresponding to a historical period can be filtered out and its statistical signature (i.e. average value and standard deviation of the real power within such period) can be extracted and profiled. An example would be to obtain the historical smart distribution box data for an appliance, extract the ‘operate’ activity or state of the appliance over the historical period and calculate the operational energy consumption, calculate the average and standard deviation over the historical period, and obtain the energy consumption profile for the electrical appliance. In some embodiments, the extraction may include step of comparison with historical data over a period of time. Once the user has configured the necessary settings, the audit service is triggered based on the customized parameters. Real power consumption (e.g. from the past twenty-four hours) is extracted from the historical readings so the average real power consumption of the appliance (over the last twenty-four hours) can be calculated. A notification in the form of electronic messages such as SMS, may be send to user if the average value of the real power is outside the appliance's profiled average with allowance for ±x standard deviation (where x is ranged from 1 to 2 and may be determined by the chosen sensitivity level).

In some embodiments, the data obtained from the activity recognition module 1008 may be used to track different electrical appliances within the premise and may be used to provide indication of normal/abnormal electricity usage relating to the premise or its occupant. In particular, the operation time and duration of operation of a number of appliances in a particular room within the premise (e.g. child's room or domestic helper's room) may be monitored. A user may create different sessions for different purpose (e.g. child monitoring, elderly monitoring and domestic helper monitoring, security monitoring). For example a user may wish to create a session for child monitoring so in the interface provided, he specifies the following non limiting parameters:

i. session name—for example “Child Monitoring”;
ii. start reporting time—for example 5 pm;
iii. end reporting time—for example 11 pm;
iv. frequency—for example repeat every day;
v. number of channels (branch current) to monitor;
vi. electronic notification intervals;
vii. Activate status;
viii. repeat on/off.

The user may also specify the electrical appliances that he want to monitor in the child's bedroom, for example light, air-conditioners and power socket outlet usage, and whether he wants notification such as SMS reporting. Then he saves the session and the monitoring start at the specified start time.

In some embodiments, any session that is activated will trigger a background data collection service if it was not triggered. At an appointed juncture or time, a consolidation service will be activated to consolidate/convert the collected data into appliance activities according to methods 1200, 1220. The step of checking against each session will be conducted to find out if any sessions (such as abnormal electricity usage or patterns) that need reporting. If yes, the notification(s) is/are composed following the relevant session setting/requirement and electronic notifications sent to the appropriate recipient via email or SMS message.

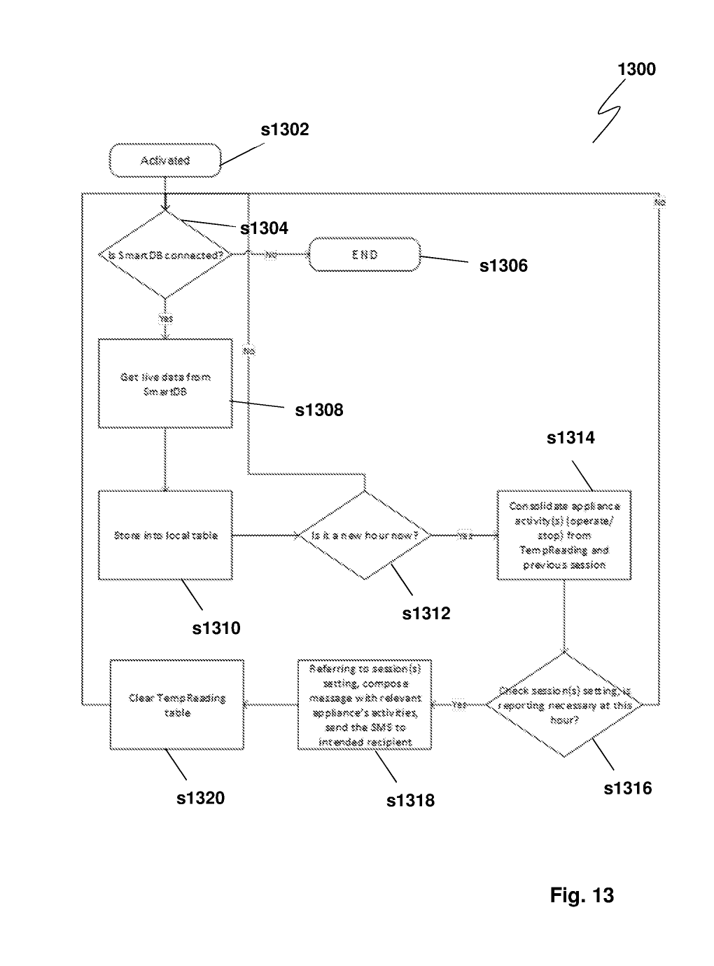

Referring to FIG. 13, a method embodiment 1300 of how data are collected and managed is illustrated. The method commences once the monitoring session is activated (step s1302). Data connection with the Smart DB or sensors are then checked at step s1304. If the Smart DB is not connected, the process terminates (step s1306). If the smart DB is connected or able to be connected, upon establishing connection live data is obtained from the smart DB (step s1308). The live data are organised and stored in a local database (not shown) within the system 1000. The method next checks if it is time for conversion and/or consolidation of data (e.g. new hour) at step s1312. If it is time for conversion and/or consolidation of data, the appliance's activity relating to operate/standby/stop are converted via methods 1220 and consolidated at step s1314 and then the system 1000 checks if it is time for reporting in step s1316. If it is not time for consolidation and conversion of data in S1312 or it is not time for reporting in S1316, the method advance directly to step S1304 to continue data collection. At step s1316, if it is time to provide a report, a notification or report will be sent to the user in accordance with his predetermined settings at step s1318. Any cache is then cleared at step s1320 and the method loops to step s1304.

In some embodiments the system 1000 may be used to monitor electrical safety. In particular, the system 1000 monitors channels current consumption continuously and issues alert and notification when necessary. Before activation, a user may set the following parameters:

i. where and when any alerts and notification is to be sent by specifying SMS contact number;
ii. duration and power rating of continuous high power consumption to trigger notification/alert; and
iii. threshold of high current to trigger warning.

Once the parameters are set, the safety monitoring is activated and real time data is received continuously and checked against each channels

Once activated, real time data is received from the sensors continuously and is compared against the current and real power rating (threshold set by a user) of each channel or current branch. When any of the rating is exceeded, the user is notified using electronic messaging such as SMS. Prior to activation, the user can configure where and when the electronic notification can be sent based on specifying a mobile identifier (MSISDN), duration and power rating of continuous high power consumption to trigger warning, and threshold of high current to trigger warning.

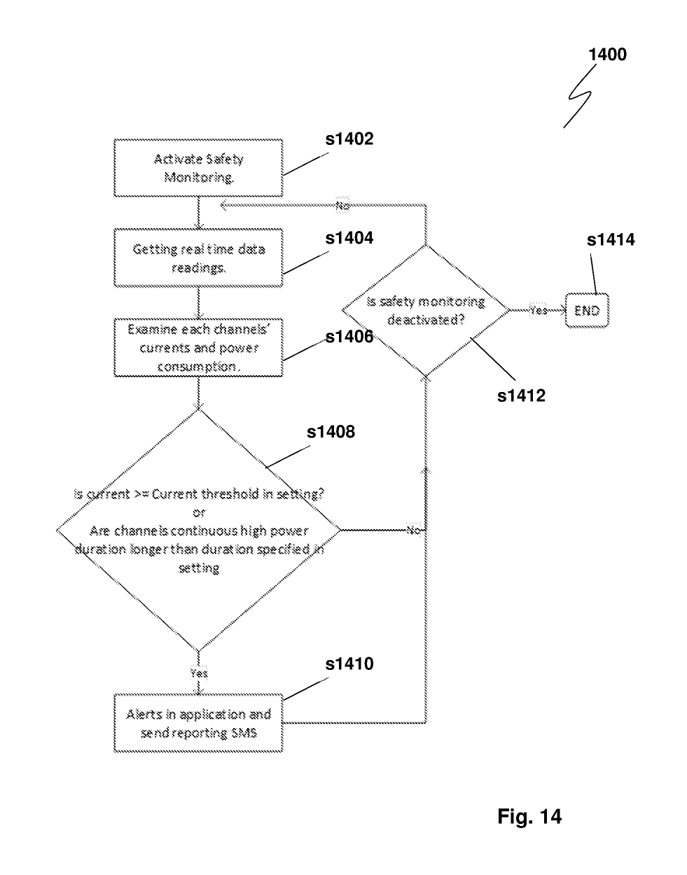

An example is shown in FIG. 14, where a method for safety monitoring 1400 is illustrated. Once the safety monitoring is activated via step s1402, the real time data readings are obtained from the smart DB in step s1404. Each channel's current and power consumption are checked at step s1406 whether they exceed any of the current or power thresholds as set by the user. At step s1408, if the current in a current branch exceeds the current threshold or if the channels continuous high power duration is longer than duration specified in the user setting, then a notification is sent to the user (step s1410). If not, the system 1000 checks if the safety monitoring is deactivated at step s1412. After the alerts or notifications have been sent, the method loops to step s1412. If safety monitoring has been deactivated, the process ends (step s1414), else, the method loops to step s1404.

In some embodiments, the identified electrical appliance and the appliance activity recognized data may be utilized to derive indications of lifestyle. Some examples are provided as follows:

(a.) drinking water consumption—analysis using electrical energy consumption to derive a non-electrical energy consumption
(b.) television watching hours—analysis based on electrical energy consumption for one type of appliance
(c.) Bathing Sessions—analysis based on electrical energy consumption for one type of appliance
(d.) Sleeping Pattern—analysis requiring multiple types of electrical appliances

One or more of the above may be displayed for a user's viewing via one or more display or user interface.

Drinking water consumption—once the appliance has been identified as an electric kettle and the activity recognition profile of the same obtained, the electrical energy consumption by the electric kettle may be used to infer the total drinking water consumption by the household. A user has to confirm through an interface setting via an app installed on his smart hand-held device that their household boils the water using the electric kettle before consumption of the same. A predetermined period (e.g. weekly and monthly) historical kettle real power can be gathered. The power is then converted to total energy using the conversion equation that 1 watt per second equals to one Joule of heat energy. A specific heat equation mathematically expressed as:

M=Q/CΔT

Where M is the total mass of water heated or boiled, Q is the heat energy added, C is the specific heat value of water, and AT is the change in temperature are used to derive the total mass of water heated or boiled.

Once the total mass of water is derived, the total mass of water cooked for the predetermined period is provided to the user with optional recommendations/advice if water consumption is significantly less than average.

Television watching hours—Once the appliance has been identified as a television and the activity recognition profile of the same obtained, the electrical energy consumption by the television set may obtained based on the recognized or identified ‘operational’ hours or sessions, such that the total watching hours by the household for a predetermined period (e.g. daily, weekly, or monthly) is obtained. The total television watching hours, daily average and latest switching off time can be provided to the user via a display interface.

Bathing Sessions—Once the appliance has been identified as an electric heater and the activity recognition profile of the same obtained, the electrical energy consumption of the electric heater may be obtained. A user has to confirm through an interface (via an app) that the household uses electric water heater for showering. As long as the water heater is detected to be “in operation” (regardless of power consumption/temperature), the length of the duration of using water heater is logged. Thereafter the total showering hours, sessional average and latest bathing time can be provided to the user via a display interface.

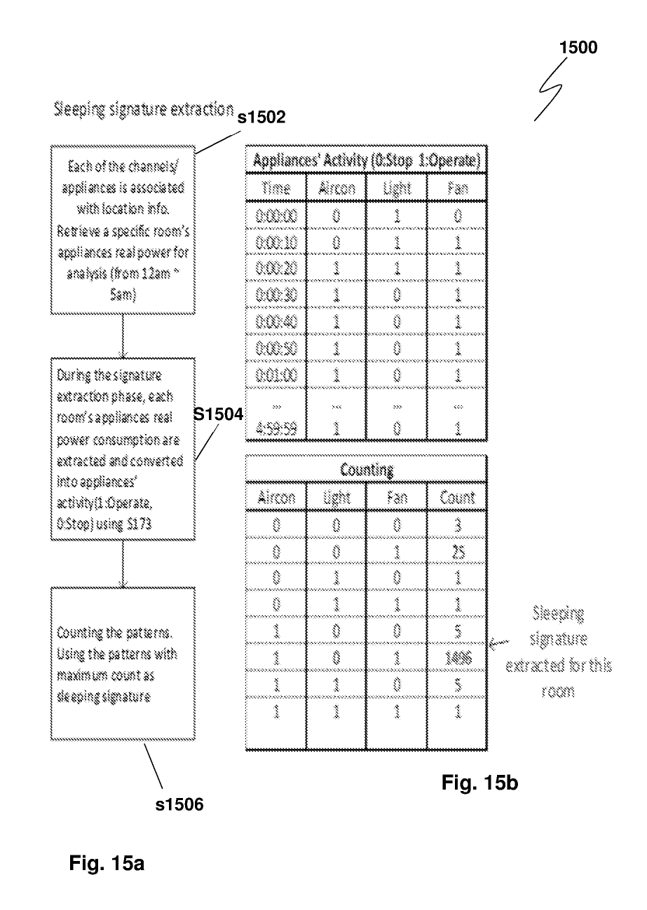

Sleeping pattern—Contrary to the previous examples which is limited to the analysis of one or one type of electrical appliance, in order to obtain the sleeping pattern, multiple types of electrical appliance need to be considered within a room. As such, it is necessary to obtain signatures or features to provide a derivation of sleeping signature of a specific room can be extracted as shown in FIG. 15a and FIG. 15b. Daily historical data obtained within a predetermined period (e.g. 12 am˜5 am) of that specific room can be used and whenever the time series data contains the signature's pattern then it can be inferred there is someone sleeping in the room. Such sleeping sessions can be visualized to user the total sleeping hours, daily average and latest sleeping time.

A method flow of sleeping signature extraction is provided in FIG. 15. The flow commences with obtaining from each branch current channel/electrical socket etc. electrical appliances that is associated with a particular location (e.g. master bedroom) that is to be analysed (step s1502).

Once the appliances to be analysed in the master bedroom are identified, the method 1120 and 1220 may be used to identify the appliances and the activity associated with the appliances (step s1504). A binary (1, 0) scheme may be implemented such that an off activity of the appliance corresponds to a ‘0’ and an operate activity correspond to ‘1’.

In an example an air-conditioner, ceiling lights and fan were identified appliances in the master bedroom. FIG. 15b shows a table form of the appliances' activity at different time intervals in blocks of 10 seconds. The sleeping pattern/signature is obtained based on a count corresponding to the maximum number of occurrences, in this case when the air-conditioner is switched on, the fan is switched on and the light is switched off (step s1506).

In some embodiments, based on the aforementioned functions or modules, tips and recommendations may be provided to the user for consideration. The following list some examples:
(1) The energy management which contains the energy audit, can provide suggestions to replace the appliance, to have a technician check the appliance or to recommend a more efficient brand.
(2) Suggestion to switch off the standby power to save money as well as carbon footprint.
(3) Notification where there are overuse or near overuse of energy compared to a previous period (e.g. last month).
(4) Drinking water reminder.
(5) Late sleeping or bathing activities detection and warning.
(6) Watching TV reminders and warnings.
(7) Sleeping pattern advices.
(8) Benchmarking of energy usage to national level to provide advice.

In some embodiments, each channel or appliance's energy audit can be a reference for the system to choose a related advertisements, for example to recommend user a more energy efficient replacement. If the user is detected often cook at home, online grocery shop or relevant products promotion can be pushed to the user's app. If the user has relatively shorter sleeping duration, a mattress, purifier or humidifier or whatever products that helps to improve the sleeping quality can be recommended to the user. Not only user can receive the advertisement, they can share their appliance's efficient energy consumption graph or testimonial to recommend the appliance they currently uses.

The above is a description of embodiments of systems and methods for relaying information. It is envisioned that those skilled in the art can design alternative embodiments of this invention that falls within the scope of the invention. In particular, it is to be appreciated that features from various embodiment(s) may be combined to form one or more additional embodiments.

1. An apparatus for installation with an electrical distribution box comprising at least one bus bar and a plurality of circuit breakers, the apparatus comprising
a sensor circuit comprising at least one passive sensor having a resistance, the at least one passive sensor arranged in series connection with the at least one bus bar and one of the plurality of circuit breakers, wherein one terminal of the at least one passive sensor is connected to the at least one bus bar and another terminal of the at least one sensor is connected to one of the plurality of circuit breakers; and
wherein the apparatus further comprises a processor to obtain a voltage signal across the at least one passive sensor and derive a corresponding current signal flowing through the at least one passive sensor.

2. The apparatus according to claim 1, wherein the sensor circuit comprises at least one bus bar for connection or superimposition onto the at least one bus bar of the electrical distribution box.

3. The apparatus according to claim 1, wherein the bus bar is a neutral conductor plate.

4. The apparatus according to claim 1, wherein the processor operates to derive at least one power parameter based on the corresponding voltage signal and corresponding current signal obtained.

5. The apparatus according to claim 1, wherein the processor comprises at least one of the following: a signal processing unit having a voltage and current amplifier, a filter, and an analogue to digital converter (ADC).

6. The apparatus according to claim 5, wherein the sensor circuit comprises a plurality of sensors and a selector device is positioned between the sensor circuit and the signal processing unit to toggle between inputs fed to the signal processing unit.

7. The apparatus according to claim 1, wherein the sensor circuit comprises one sensor and a selector device operable to toggle the series connection between the one sensor and each of the plurality of circuit breakers.

8. The apparatus according to claim 4, wherein the at least one power parameter includes root mean square voltage, root mean square current, active power, reactive power, apparent power, power factor, frequency, harmonics profile.

9. The apparatus according claim 1, wherein the sensor circuit and processor are mounted on a single circuit board.

10. The apparatus according to claim 1, wherein the sensor circuit is mounted on a first circuit board and the processor is mounted on a second circuit board, wherein the second circuit board comprises a short circuit protection circuit.

11. The apparatus according to claim 1, wherein the processor comprises a communication module.

12. The apparatus according to claim 11, wherein the communication module comprises a wireless transceiver arranged to send and receive data with a third party server.

13. The apparatus according to claim 12, wherein the at least one wireless transceiver is capable of supporting at least one of the following wireless communication protocols: Wi-Fi, ZigBee, Zwave, wireless mobile telecommunications.

14. The apparatus according to claim 11, wherein the apparatus is operable to switch between a first communication mode where the apparatus is configured as a client, and a second communication mode where the apparatus is configured as an application server.

15. A system for energy management comprising
an electrical distribution box installed with the apparatus of claim 11; and
a server arranged in data communication with the apparatus to receive the obtained voltage, current data signal and at least one power parameter, wherein the electrical distribution box further comprises a detector to detect and establish a data communication link with the server.

16. The system according to claim 15, wherein if the electrical distribution box is unable to establish a data communication link with the server after a predetermined number of retries, the data communication link is switched to a communication with a computer device.

17. The system according to claim 15, wherein the distribution box comprises a real time clock module arranged to provide a time stamp for each voltage or current data signal.

18. The system according to claim 17, wherein upon a power interruption or shutdown, the real time clock module is reset to a predetermined setting after power is restored and a flag indicating that time stamp correction is required is set.

19. The system according to claim 18, wherein upon detection that time synchronization is available, the real time clock module is restored to the correct time and all affected time stamps are time shifted.

20. A management system comprising
an apparatus according to claim 1, the apparatus arranged to receive a voltage dataset and a current dataset from a plurality of electrical appliances linked to a channel of the electrical distribution box over a predetermined period;
a load identification module operable to identify each of the plurality of electrical appliances based on the voltage and current dataset received; and
an electrical appliance activity recognition module operable to extract at least two states of each electrical appliance over the predetermined period.

21. The system according to claim 20, wherein the electrical appliance activity recognition module is operable to extract the at least two states of each of the plurality of electrical appliances over the predetermined period to obtain an energy consumption profile for each of the electrical appliance.

22. The system according to claim 20, wherein the sensor device is configured to derive at least one power parameter, the at least one power parameter includes active power, reactive power, apparent power, power factor, harmonics.

23. The system according to claim 20, wherein the load identification module operates to identify each of the plurality of electrical appliances based on extraction of a plurality of signatures from the voltage and current dataset obtained over a predetermined period.

24. The system according to claim 23, wherein the plurality of signatures comprise zero current count, on-off cycle count, and maximum power consumption.

25. The system according to claim 23, wherein the plurality of electrical appliances are classified based on a k-nearest neighbour algorithm.

26. The system according to claim 20, further comprises an energy consumption estimation module to receive past voltage dataset and current dataset for estimating a future period of energy consumption, the energy consumption module comprises at least one user interface suitable for customization by a user as to the level of granularity.

27. The system according to claim 20, further comprises an energy audit module wherein an operational state is extracted from the electrical appliance activity recognition module for calculation of at least two statistical parameters.

28. The system according to claim 20, further comprises a monitoring module operable to activate the load identification module and/or the electrical appliance activity recognition module for the collection of the voltage and current dataset, for detecting of abnormal electricity usage or pattern.

29. The system according to claim 20, further comprises an electrical safety module operable to receive thresholds of current and power rating and electronically notify a user once a threshold for current or power is exceeded.

30. The system according to claim 20, further comprises a lifestyle module operable to retrieve energy consumption data from the voltage and current dataset to derive an indication relating to at least one of the following: a non-electrical energy consumption, electrical energy consumption relating to one type of electrical appliance, and electrical energy consumption relating to multiple electrical appliances within a location.

31. A management system comprising
at least one sensor arranged to receive a voltage dataset and a current dataset from a plurality of electrical appliances linked to a channel of an electrical distribution box over a predetermined period;
a load identification module operable to identify each of the plurality of electrical appliances based on the voltage and current dataset received; and
an electrical appliance activity recognition module operable to extract at least two states of each electrical appliance over the predetermined period.

32. The system according to claim 31, further comprises an energy consumption estimation module to receive past voltage dataset and current dataset for estimating a future period of energy consumption, the energy consumption module comprises at least one user interface suitable for customization by a user as to the level of granularity.

33. The system according to claim 31, further comprises an energy audit module wherein an operational state is extracted from the electrical appliance activity recognition module for calculation of at least two statistical parameters.

34. The system according to claim 31, further comprises a monitoring module operable to activate the load identification module and/or the electrical appliance activity recognition module for the collection of the voltage and current dataset, for detecting of abnormal electricity usage or pattern.

35. The system according to claim 31, further comprises an electrical safety module operable to receive thresholds of current and power rating and electronically notify a user once a threshold for current or power is exceeded.

36. The system according to claim 31, further comprises a lifestyle module operable to retrieve energy consumption data from the voltage and current dataset to derive an indication relating to at least one of the following: a non-electrical energy consumption, electrical energy consumption relating to one type of electrical appliance, and electrical energy consumption relating to multiple electrical appliances within a location.

37. The system according to claim 31, wherein the electrical appliance activity recognition module is operable to extract the at least two states of each of the plurality of electrical appliances over the predetermined period to obtain an energy consumption profile for each of the electrical appliance.

38. An apparatus for installation with an electrical distribution box comprising
at least one neutral bus bar and a plurality of circuit breakers, the apparatus comprises a sensor circuit comprising at least one sensor arranged in series connection with the at least one neutral bus bar and one of the plurality of circuit breakers, wherein one terminal of the at least one sensor is connected to the at least one neutral bus bar and another terminal of the at least one sensor is connected to one of the plurality of circuit breakers; and
wherein the apparatus further comprises a processor to obtain a voltage signal across the at least one sensor and a corresponding current signal flowing through the at least one sensor.
